(19) United States
(12) Patent Application Publication
(10) Pub. No.: US 2024/0321779 A1
(43) Pub. Date: Sep. 26, 2024

(54) INTERCONNECTION MEMBER AND METHOD OF MANUFACTURING THE SAME

(71) Applicants: Kabushiki Kaisha Toshiba, Tokyo (JP); Toshiba Electronic Devices & Storage Corporation, Tokyo (JP)

(72) Inventors: Kei OBARA, Kawasaki Kanagawa (JP); Kazumichi TSUMURA, Shinagawa Tokyo (JP)

(21) Appl. No.: 18/458,122

(22) Filed: Aug. 29, 2023

(30) Foreign Application Priority Data
Mar. 22, 2023 (JP) 2023-045027

(51) Int. Cl. H01L 23/58; H01L 21/3065; H01L 21/3213

(52) U.S. Cl. CPC H01L 23/585; H01L 21/3065; H01L 21/32135

(57) ABSTRACT

A width of a first through hole is greater than a width of a second through hole in a direction orthogonal to a first direction. The first through hole also extends to a part of an interconnection portion in the first direction. A side surface of the first through hole includes a first side surface portion positioned on a substrate and a second side surface portion positioned on the part of the interconnection portion. The interconnection portion includes a third face facing a first face of the substrate, a fourth face positioned on an opposite side with respect to the third face in the first direction, and a fifth face. The fifth face is continuous with the second side surface portion of the first through hole and a side surface of a conductive film, and includes an end surface of the conductive film in the first direction.

### CROSS-REFERENCE TO RELATED APPLICATION

This application is based upon and claims the benefit of priority from Japanese Patent Application No. 2023-045027, filed on Mar. 22, 2023; the entire contents of which are incorporated herein by reference.

### FIELD

Embodiments described herein relate generally to an interconnection member and a method of manufacturing an interconnection member.

### BACKGROUND

An interconnection member having a through hole may be required to cover a side surface of the through hole with a conductive film.

### BRIEF DESCRIPTION OF THE DRAWINGS

FIG. 1A is a schematic plan view of an interconnection member of an embodiment, and FIG. 1B is a cross-sectional view taken along a line A-A in FIG. 1A;

FIG. 2A and FIG. 2B are schematic cross-sectional views showing a method of manufacturing the interconnection member according to the first embodiment;

FIG. 3A is a schematic plan view of an interconnection member according to a variation of the embodiment, and FIG. 3B is a cross-sectional view taken along a line B-B in FIG. 3A; and

FIG. 4A and FIG. 4B are schematic cross-sectional views showing a method of manufacturing an interconnection member according to a comparative example.

### DETAILED DESCRIPTION

According to one embodiment, an interconnection member includes a substrate including a first face, a second face positioned on an opposite side with respect to the first face in a first direction, and a first through hole extending in the first direction; and an interconnection portion provided on the first face of the substrate, including an insulating layer, an interconnection layer provided in the insulating layer, a second through hole extending in the first direction and continuous with the first through hole, and a conductive film provided on a side surface of the second through hole, a width of the first through hole being greater than a width of the second through hole in a direction orthogonal to the first direction, the first through hole also extending to a part of the interconnection portion in the first direction, and a side surface of the first through hole including a first side surface portion positioned on the substrate and a second side surface portion positioned on the part of the interconnection portion, and the interconnection portion including a third face facing the first face of the substrate, a fourth face positioned on an opposite side with respect to the third face in the first direction, and a fifth face, the fifth face continuous with the second side surface portion of the first through hole and a side surface of the conductive film and including an end surface of the conductive film in the first direction.

Hereinafter, an embodiment will be described with reference to the drawings.

The drawings are schematic or conceptual. A relationship between a thickness and a width of each portion, a ratio of sizes between portions, and the like are not necessarily the same as the actual ones. Even if the same portions are shown, dimensions and ratios may be shown differently from each other in the drawings.

Same components are denoted by same reference numerals.

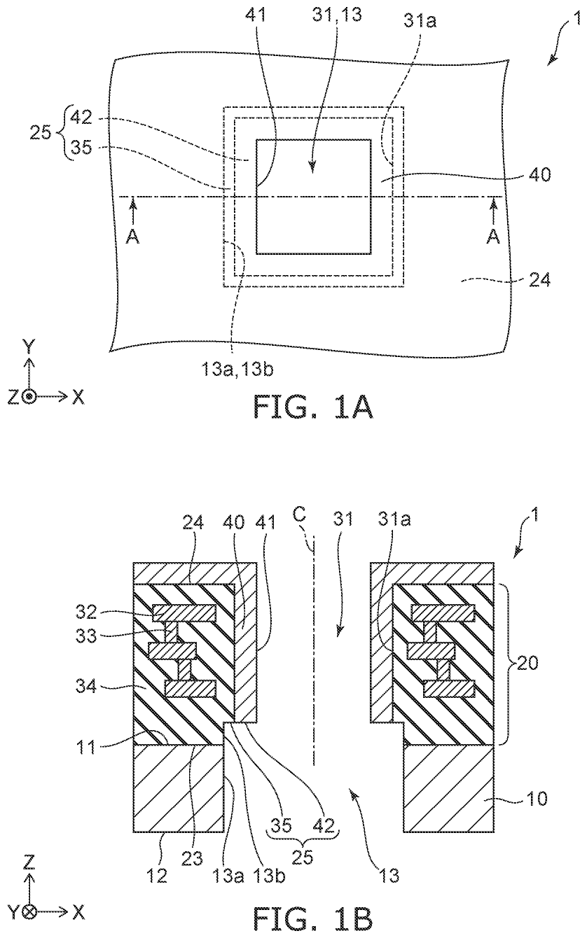

FIG. 1A is a schematic plan view of an interconnection member 1 of an embodiment, and FIG. 1B is a cross-sectional view taken along a line A-A in FIG. 1A. The interconnection member 1 includes a substrate 10 and an interconnection portion 20. The substrate 10 and the interconnection portion 20 are stacked in a first direction Z. Two directions orthogonal to the first direction Z are referred to as a second direction X and a third direction Y. The second direction X and the third direction Y are orthogonal to each other.

The substrate 10 includes a first face 11 and a second face 12 positioned on an opposite side with respect to the first face 11 in the first direction Z. The substrate 10 has a first through hole 13 penetrating from the first face 11 to the second face 12 and extending in the first direction Z. The substrate 10 is, for example, a silicon substrate.

The interconnection portion 20 is provided on the first face 11 of the substrate 10. The interconnection portion 20 includes a third face 23 facing the first face 11 of the substrate 10, and a fourth face 24 positioned on an opposite side with respect to the third face 23 in the first direction Z. The interconnection portion 20 includes an insulating layer 34 and interconnection layers 32 provided in the insulating layer 34. The interconnection portion 20 can include, for example, the multiple interconnection layers 32 and conductive vias 33 connecting the interconnection layers 32 of different layers. The interconnection portion 20 has a second through hole 31 extending in the first direction Z and continuous with the first through hole 13 in the first direction Z.

The interconnection portion 20 further includes a conductive film 40 provided on a side surface 31a of the second through hole 31. The conductive film 40 can also be provided on the fourth face 24 of the interconnection portion 20. The conductive film 40 provided on the fourth face 24 of the interconnection portion 20 can be patterned. As the conductive film 40, for example, a titanium film, a titanium nitride film, or a stacked film of a titanium film and a titanium nitride film can be used.

As shown in FIG. 1A, the second through hole 31 and the first through hole 13 each have a square shape in a plan view. The conductive film 40 continuously covers the entire side surface 31a of the second through hole 31. In addition, an axis passing through a center of the second through hole 31 (in the example, an intersection point of two diagonal lines of the square second through hole 31) is virtually shown as a central axis C of the second through hole 31 in FIG. 1B.

In the direction orthogonal to the first direction Z (the second direction X and the third direction Y), a width of the first through hole 13 is larger than a width of the second through hole 31. The first through hole 13 also extends to a part of the interconnection portion 20 in the first direction Z, and a side surface of the first through hole 13 includes a first side surface portion 13a positioned on the substrate 10 and a second side surface portion 13b positioned on the part of the interconnection portion 20. The insulating layer 34 is exposed to the first through hole 13 on the second side surface portion 13b.

The first side surface portion 13a and the second side surface portion 13b are continuous in the first direction Z without forming a step. A step is formed between the side surface of the first through hole 13 and the side surface 31a of the second through hole 31. A step is also formed between the side surface of the first through hole 13 and a side surface 41 of the conductive film 40.

The interconnection portion 20 further includes a fifth face 25 continuous with the second side surface portion 13b of the first through hole 13 and the side surface 41 of the conductive film 40. The fifth face 25 is positioned at a boundary between the first through hole 13 and the second through hole 31. A step is formed between the fifth face 25 and the third face 23. As shown in FIG. 1A, the fifth face 25 is annularly formed between the side surface 41 of the conductive film 40 and the second side surface portion 13b of the first through hole 13. As shown in FIG. 1B, the fifth face 25 faces the first through hole 13 in the first direction Z.

The fifth face 25 includes an end surface 42 of the conductive film 40 in the first direction Z (a lower end surface in FIG. 1B). The fifth face 25 includes a surface 35 of the insulating layer 34 positioned on a side closer to the second side surface portion 13b of the first through hole 13 than is the end surface 42 of the conductive film 40 in the direction orthogonal to the first direction Z (the second direction X and the third direction Y). The end surface 42 of the conductive film 40 is positioned on a side closer to the central axis C of the second through hole 31 than is the surface 35 of the insulating layer 34.

For example, a charged particle beam passes through the second through hole 31 and the first through hole 13. The side surface 31a of the second through hole 31 is covered with the conductive film 40, and the insulating layer 34 of the interconnection portion 20 is not exposed on the side surface of the second through hole 31. Accordingly, it is possible to prevent charging of the side surface of the insulating layer 34 and prevent abnormal deflection of the charged particle beam. As a result, reliability of the interconnection member 1 can be enhanced.

On the fifth face 25 of the interconnection portion 20, the end surface 42 of the conductive film 40 is exposed on a side closer to the central axis C of the second through hole 31, that is, a portion closer to a passage path of the charged particle beam. Accordingly, the abnormal deflection of the charged particle beam can be prevented.

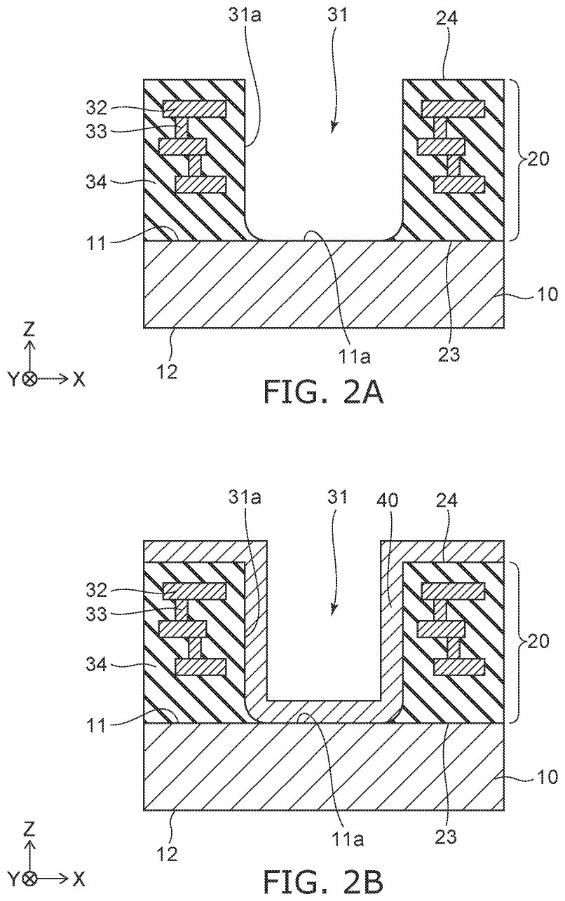

Next, a method of manufacturing the interconnection member 1 according to the embodiment will be described with reference to FIGS. 2A and 2B.

As shown in FIG. 2A, after the interconnection portion 20 is formed on the first face 11 of the substrate 10, the second through hole 31 is formed in the interconnection portion 20. The second through hole 31 can be formed by, for example, a reactive ion etching (RIE) method. The second through hole 31 reaches the first face 11 of the substrate 10, and a part 11a of the first face 11 of the substrate 10 is exposed at a bottom surface of the second through hole 31.

After the second through hole 31 is formed, as shown in FIG. 2B, the conductive film 40 is formed on the side surface 31a and the bottom surface (the part 11a of the first face 11 of the substrate 10) of the second through hole 31. For example, the conductive film 40 that is continuous with the fourth face 24 of the interconnection portion 20, the side surface 31a and the bottom surface of the second through hole 31 can be formed by a sputtering method. A part or all of the conductive film 40 on the fourth face 24 of the interconnection portion 20 may be removed.

After the conductive film 40 is formed, the first through hole 13 continuous from a second face 12 side of the substrate 10 to the second through hole 31 is formed in the substrate 10. For example, the substrate 10 is etched in the first direction Z from the second face 12 side of the substrate 10 by the RIE method. For example, when the substrate 10 is a silicon substrate, a fluorine-based gas (a SF₆ gas or the like) can be used as an etching gas. When the substrate 10 is etched from the second face 12 to the first face 11, the conductive film 40 formed on the bottom surface of the second through hole 31 is exposed. Thereafter, by switching the etching gas or using a same etching gas, the conductive film 40 formed on the bottom surface of the second through hole 31 is etched and removed. For example, when the conductive film 40 is a titanium film, a chlorine-based gas (a mixed gas of BCl₃ and Cl₂, or the like) can be used as the etching gas. In addition, both the silicon substrate and the titanium film can be etched by using the fluorine-based gas (the SF₆ gas or the like). In order to etch the conductive film 40 formed on the bottom surface of the second through hole 31, the first through hole 13 is also formed to extend to a part of the interconnection portion 20 in the first direction Z.

When the first through hole 13 is formed to a part of the interconnection portion 20, a part of the insulating layer 34 is removed, and a portion where the insulating layer 34 is exposed appears on the side surface of the first through hole 13. That is, as shown in FIG. 1B, the side surface of the first through hole 13 includes the first side surface portion 13a positioned on the substrate 10 and the second side surface portion 13b positioned on the part of the interconnection portion 20. The etching gas for removing a part of the insulating layer 34 may be the same as or different from the etching gas for removing the substrate 10.

In order to secure a desired width necessary for the passage of the charged particle beam even if the first through hole 13 is misaligned with respect to the second through hole 31, the width of the first through hole 13 is larger than the width of the second through hole 31 in the direction orthogonal to the first direction Z. Therefore, as shown in FIG. 1B, a step is formed between the side surface 41 of the conductive film 40 formed on the side surface 31a of the second through hole 31 and the side surface of the first through hole 13. Due to the step, the fifth face 25 continuous with the side surface of the first through hole 13 and the side surface 41 of the conductive film 40 is formed in the interconnection portion 20.

According to a process of forming the first through hole 13 described above, the end surface 42 of the conductive film 40 is exposed on the fifth face 25 positioned at the boundary between the first through hole 13 and the second through hole 31.

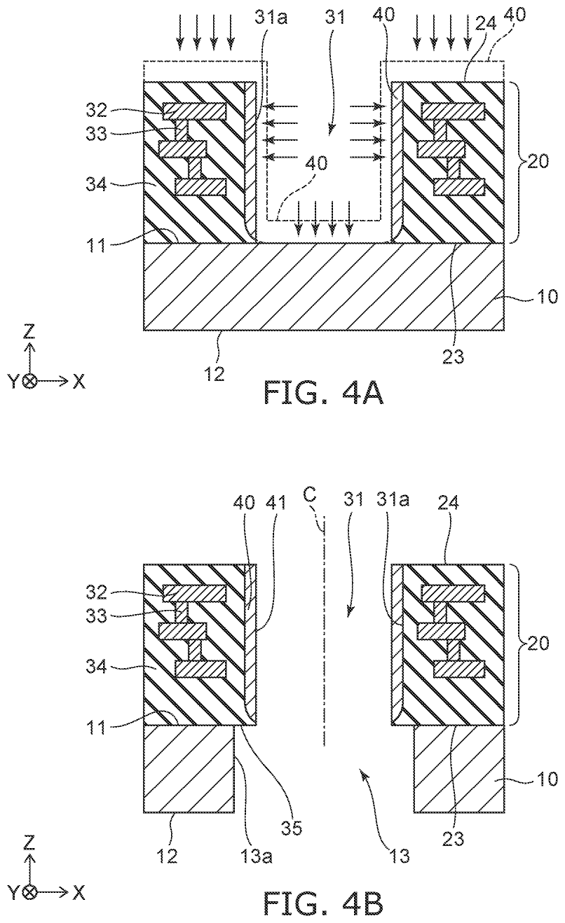

FIGS. 4A and 4B show a method of manufacturing an interconnection member according to a comparative example.

In the comparative example, after the conductive film 40 is formed on the side surface 31a and the bottom surface of the second through hole 31, as shown in FIG. 4A, the conductive film 40 is etched back by the RIE method before the first through hole 13 is formed, and the conductive film 40 formed on the bottom surface of the second through hole 31 is removed. In FIG. 4A, the surface of the conductive film 40 before the etch-back is shown by a broken line.

Thereafter, as shown in FIG. 4B, the substrate 10 is etched in the first direction Z from the second face 12 side of the substrate 10 to form the first through hole 13. At this time, the interconnection portion 20 is not etched.

According to the method in the comparative example, the surface 35 of the insulating layer 34 is also exposed on a side closer to the central axis C of the second through hole 31 on a lower surface of the interconnection portion 20 that is annularly formed and exposed from the substrate 10 at the boundary between the first through hole 13 and the second through hole 31. Therefore, there is a concern of the abnormal deflection of the charged particle beam due to charging of the surface 35 of the insulating layer 34.

According to the embodiment, as shown in FIG. 1B, the end surface 42 of the conductive film 40 is positioned on a side closer to the central axis C of the second through hole 31 on the fifth face 25 of the interconnection portion 20 that is annularly formed and exposed from the substrate 10 at the boundary between the first through hole 13 and the second through hole 31, and the surface 35 of the insulating layer 34 is not exposed. Accordingly, the abnormal deflection of the charged particle beam can be prevented.

In addition, in the comparative example, as shown in FIG. 4A, when the conductive film 40 is etched back from a fourth face 24 side of the interconnection portion 20, side etching progresses toward the conductive film 40 formed on the side surface 31a of the second through hole 31, and there is a concern that a film thickness of the conductive film 40 left on the side surface 31a of the second through hole 31 decreases. Accordingly, a desired charging preventing function may not be exhibited.

According to the embodiment, since the conductive film 40 formed on the bottom surface of the second through hole 31 is removed by etching from a substrate 10 side, etching of the conductive film 40 formed on the side surface 31a of the second through hole 31 can be prevented.

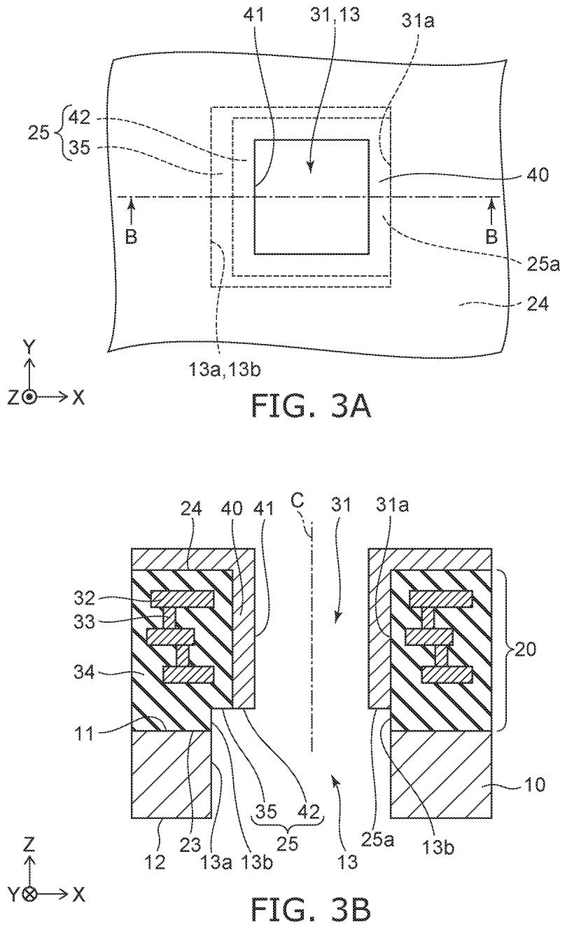

FIG. 3A is a schematic plan view of an interconnection member according to a variation of the embodiment, and FIG. 3B is a cross-sectional view taken along a line B-B in FIG. 3A. In the variation, a part 25a of the fifth face 25 of the interconnection portion 20 includes only the end surface 42 of the conductive film 40, and does not include the surface 35 of the insulating layer 34 on a second side surface portion 13b side. In the fifth face 25 that is annularly formed in a plan view, the part 25a of the fifth face 25 is positioned, for example, on a right side in the second direction X with respect to the central axis C of the second through hole 31. Since the surface 35 of the insulating layer 34 is not exposed on the part 25a of the fifth face 25, an effect of preventing abnormal deflection of the charged particle beam can be enhanced.

For example, when a position of the first through hole 13 in the second direction X with respect to the second through hole 31 is shifted to a left side from the example shown in FIGS. 1A and 1B, a structure of the variation can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. An interconnection member comprising:
a substrate including a first face, a second face positioned on an opposite side with respect to the first face in a first direction, and a first through hole extending in the first direction; and
an interconnection portion provided on the first face of the substrate, including an insulating layer, an interconnection layer provided in the insulating layer, a second through hole extending in the first direction and continuous with the first through hole, and a conductive film provided on a side surface of the second through hole,
a width of the first through hole being greater than a width of the second through hole in a direction orthogonal to the first direction,
the first through hole also extending to a part of the interconnection portion in the first direction, and a side surface of the first through hole including a first side surface portion positioned on the substrate and a second side surface portion positioned on the part of the interconnection portion, and
the interconnection portion including a third face facing the first face of the substrate, a fourth face positioned on an opposite side with respect to the third face in the first direction, and a fifth face, the fifth face continuous with the second side surface portion of the first through hole and a side surface of the conductive film and including an end surface of the conductive film in the first direction.

2. The member according to claim 1, wherein
the fifth face of the interconnection portion includes the end surface of the conductive film, and a surface of the insulating layer positioned on a side closer to the second side surface portion of the first through hole than the end surface of the conductive film in the direction orthogonal to the first direction.

3. The member according to claim 1, wherein
a part of the fifth face of the interconnection portion includes only the end surface of the conductive film, and does not include the surface of the insulating layer on a second side surface portion side.

4. The member according to claim 1, wherein
the conductive film is a titanium film, a titanium nitride film, or a stacked film of a titanium film and a titanium nitride film.

5. The member according to claim 1, wherein
the conductive film continuously covers an entire side surface of the second through hole.

6. The member according to claim 1, wherein
the insulating layer of the interconnection portion is not exposed on the side surface of the second through hole.

7. The member according to claim 1, wherein
the fifth face is annularly formed between the side surface of the conductive film and the second side surface portion of the first through hole.

8. The member according to claim 1, wherein
the conductive film is also provided on the fourth face of the interconnection portion.

9. A method of manufacturing an interconnection member, comprising:
forming an interconnection portion including an insulating layer and an interconnection layer provided in the insulating layer, on a first face of a substrate including the first face and a second face positioned on an opposite side with respect to the first face in a first direction;
forming, in the interconnection portion, a second through hole reaching the first face of the substrate;
forming a conductive film on a side surface and a bottom surface of the second through hole; and
forming a first through hole, that is continuous with the second through hole, in the substrate from a second face side of the substrate, and removing the conductive film formed on the bottom surface of the second through hole,
in the forming the first through hole, a width of the first through hole being larger than a width of the second through hole in a direction orthogonal to the first direction, the first through hole also extending to a part of the interconnection portion in the first direction, and an end surface of the conductive film in the first direction formed on a side surface of the second through hole being exposed at a boundary between the first through hole and the second through hole.

10. The method according to claim 9, wherein
in the forming the first through hole, the substrate and the conductive film are etched by a reactive ion etching (RIE) method.

11. The method according to claim 10, wherein
after the substrate is etched, a gas is switched to etch the conductive film.

12. The method according to claim 10, wherein
the substrate is a silicon substrate, the conductive film is a titanium film, and
the substrate and the conductive film are etched using a same gas containing fluorine.
